(19) United States
(12) Patent Application Publication
(10) Pub. No.: US 2025/0076367 A1
(43) Pub. Date: Mar. 6, 2025

(54) SEMICONDUCTOR WAFER HANDLING APPARATUS AND SEMICONDUCTOR WAFER TESTING SYSTEM

(71) Applicant: ADVANTEST Corporation, Tokyo (JP)

(72) Inventors: Aritomo Kikuchi, Tokyo (JP); Toshiyuki Kiyokawa, Tokyo (JP)

(73) Assignee: ADVANTEST Corporation, Tokyo (JP)

(21) Appl. No.: 18/817,872

(22) Filed: Aug. 28, 2024

(30) Foreign Application Priority Data
Aug. 31, 2023 (JP) 2023-141581

(51) Int. Cl. G01R 31/28

(52) U.S. Cl. CPC G01R 31/2867; G01R 31/2875; G01R 31/2877

(57) ABSTRACT

A semiconductor wafer handling apparatus moves a semiconductor wafer including a first surface on which a terminal of one or more device under tests (DUTs) is disposed and presses the terminal against a contactor of a probe card. The semiconductor wafer handling apparatus includes: a holder that holds the semiconductor wafer such that the first surface and a second surface of the semiconductor wafer are at least partially exposed; a first moving device that relatively moves the holder with respect to the probe card; a temperature adjusting device that contacts the second surface of the semiconductor wafer and adjusts a temperature of the DUTs; and a second moving device that relatively moves the temperature adjusting device with respect to the semiconductor wafer held by the holder.

### CROSS-REFERENCE TO RELATED APPLICATIONS

The present application claims priority from Japanese Patent Application No. 2023-141581 filed on Aug. 31, 2023, the contents of which are incorporated herein by reference in their entirety.

### BACKGROUND

### Technical Field

The present invention relates to a semiconductor wafer handling apparatus that handles a semiconductor wafer for testing a circuit element to be tested (DUT: Device Under Test) formed in the semiconductor wafer and a semiconductor wafer testing system that includes the semiconductor wafer handling apparatus.

### Description of Related Art

As a wafer testing system that tests a semiconductor device formed in a semiconductor wafer, one including a wafer chuck that holds the semiconductor wafer and a temperature adjusting means that adjusts the temperature of the semiconductor wafer is known (refer to, for example, Patent Document 1).

### PATENT DOCUMENT

PATENT DOCUMENT 1: JP 2007-129090 A

In the above-described wafer testing system, the temperature adjusting means is disposed in the wafer chuck that holds the entire surface of the semiconductor wafer. Therefore, the temperature adjusting means adjusts the temperature of the entire semiconductor wafer via the wafer chuck, and it is difficult to quickly adjust the temperature in accordance with the amount of heat generated by the semiconductor device.

### SUMMARY

One or more embodiments of the present invention provide a semiconductor wafer handling apparatus and a semiconductor wafer testing system capable of speeding up the temperature adjustment of the DUT.

[1] Aspect 1 of the present invention is a semiconductor wafer handling apparatus that moves a semiconductor wafer comprising a first surface on which a terminal of one or more device under tests (DUTs) is disposed and presses the terminal against a contactor of a probe card, the semiconductor wafer handling apparatus comprising: a holder that holds the semiconductor wafer such that the first surface and a second surface of the semiconductor wafer are at least partially exposed; a first moving device that relatively moves the holder with respect to the probe card; a temperature adjusting device that contacts the second surface of the semiconductor wafer and adjusts a temperature of the DUTs; and a second moving device that relatively moves the temperature adjusting device with respect to the semiconductor wafer held by the holder.

[2] Aspect 2 of the present invention may be the semiconductor wafer handling apparatus of Aspect 1, wherein the temperature adjusting device may comprise a first contact surface that contacts the second surface of the semiconductor wafer, the first contact surface may have a size capable of contacting N number of the DUTs formed in the semiconductor wafer, and the N number may be a natural number greater than or equal to 1 and less than or equal to 8.

[3] Aspect 3 of the present invention may be the semiconductor wafer handling apparatus of Aspect 1 or 2, wherein the holder may hold an outer peripheral part of the second surface of the semiconductor wafer such that the second surface of the semiconductor wafer is at least partially exposed, and the temperature adjusting device may contact an exposed part of the second surface from the holder.

[4] Aspect 4 of the present invention may be the semiconductor wafer handling apparatus of any one of Aspects 1 to 3, wherein the holder may comprise an annular holding part that holds an outer peripheral part of the second surface of the semiconductor wafer.

[5] Aspect 5 of the present invention may be the semiconductor wafer handling apparatus of Aspect 1 or 2, wherein the holder may hold an outer peripheral part of the first surface of the semiconductor wafer, and the temperature adjusting device may contact the second surface of the semiconductor wafer.

[6] Aspect 6 of the present invention may be the semiconductor wafer handling apparatus of any one of Aspects 1, 2 and 5, wherein the holder may comprise an annular holding part that holds an outer peripheral part of the first surface of the semiconductor wafer.

[7] Aspect 7 of the present invention may be the semiconductor wafer handling apparatus of any one of Aspects 1 to 6, wherein the temperature adjusting device may comprise: a contact block that comprises a first contact surface that contacts the second surface of the semiconductor wafer; and at least one of a heating device that heats the DUTs via the contact block and a cooling device that cools the DUTs via the contact block.

[8] Aspect 8 of the present invention may be the semiconductor wafer handling apparatus of any one of Aspects 1 to 6, wherein the temperature adjusting device may comprise: a heating device that contacts the second surface of the semiconductor wafer and heats the DUTs; and a cooling block that holds the heating device and comprises a flow path through which a coolant passes.

[9] Aspect 9 of the present invention may be the semiconductor wafer handling apparatus of Aspect 8, wherein the cooling block may comprise a contact part that surrounds an outer periphery of the heating device and contacts the second surface of the semiconductor wafer.

[10] Aspect 10 of the present invention may be the semiconductor wafer handling apparatus of Aspect 9, wherein the heating device may comprise a planar heater, the planar heater may comprise: a first heater surface that contacts the second surface of the semiconductor wafer; and a second heater surface opposite to the first heater surface, and the cooling block may comprise a second contact surface contacting the second heater surface.

[11] Aspect 11 of the present invention may be the semiconductor wafer handling apparatus of Aspect 9 or 10, wherein the flow path may pass through an inside of the contact part.

[12] Aspect 12 of the present invention may be the semiconductor wafer handling apparatus of any one of Aspects 8 to 11, wherein the semiconductor wafer handling apparatus may comprise a plurality of temperature adjusting devices including the temperature adjusting device.

[13] Aspect 13 of the present invention may be the semiconductor wafer handling apparatus of Aspect 12, wherein the temperature adjusting devices may individually correspond to the DUTs included in the semiconductor wafer.

[14] Aspect 14 of the present invention may be the semiconductor wafer handling apparatus of any one of Aspects 1 to 13, wherein the semiconductor wafer handling apparatus may comprise: a controller that controls the first and second moving devices, and the controller may control the first and second moving devices to bring the holder and the temperature adjusting device closer to the probe card in a pressing direction of the DUTs against the probe card and to press the terminal of the DUTs against the contactor of the probe card.

[15] Aspect 15 of the present invention may be the semiconductor wafer handling apparatus of any one of Aspects 1 to 14, wherein each of the DUTs may comprise an optical connection part, and the semiconductor wafer handling apparatus may comprise: an optical probe that inputs and outputs an optical signal to and from the optical connection part; and a third moving device that moves the optical probe.

[16] Aspect 16 of the present invention may be the semiconductor wafer handling apparatus of Aspect 15, wherein the terminal may be disposed on the first surface of the semiconductor wafer, and the optical connection part may be disposed on the second surface of the semiconductor wafer.

[17] Aspect 17 of the present invention may be the semiconductor wafer handling apparatus of Aspect 15 or 16, wherein the temperature adjusting device may comprise: a first contact surface that contacts the second surface of the semiconductor wafer; and a recess that opens to the first contact surface, and the optical probe may be inserted in the recess so that the optical probe is relatively movable with respect to the temperature adjusting device.

[18] Aspect 18 of the present invention may be the semiconductor wafer handling apparatus of Aspect 15 or 16, wherein the temperature adjusting device may comprise: a first contact surface that contacts the second surface of the semiconductor wafer; and an insertion that opens to the first contact surface, and the optical probe may be inserted in the insertion hole so that the optical probe is relatively movable with respect to the temperature adjusting device.

[19] Aspect 19 of the present invention may be the semiconductor wafer handling apparatus of any one of Aspects 15 to 18, wherein the optical probe may comprise an optical transmission path that transmits an optical signal.

[20] Aspect 20 of the present invention may be the semiconductor wafer handling apparatus of any one of Aspects 15 to 19, wherein the optical connection part may include a grating coupler.

[21] Aspect 21 of the present invention may be the semiconductor wafer handling apparatus of any one of Aspects 15 to 20, wherein the second moving device may relatively move the temperature adjusting device and the third moving device with respect to the semiconductor wafer held by the holder.

[22] Aspect 22 of the present invention may be the semiconductor wafer handling apparatus of Aspect 21, wherein the second moving device may comprise a support member to which the temperature adjusting device and the third moving device are fixed, and the third moving device may relatively move the optical probe with respect to the temperature adjusting device.

[23] Aspect 23 of the present invention may be the semiconductor wafer handling apparatus of any one of Aspects 15 to 22, wherein the temperature adjusting device may comprise a first contact surface that contacts the second surface of the semiconductor wafer, the first contact surface may have a size capable of contacting N number of the DUTs formed in the semiconductor wafer, the semiconductor wafer handling apparatus may comprise: N number of optical probes disposed to correspond to the N number of the DUTs; and N number of third moving devices that move the N number of the optical probes independently of each other, and the N number may be a natural number greater than or equal to 1 and less than or equal to 8.

[24] Aspect 24 of the present invention may be the semiconductor wafer handling apparatus of Aspect 23, wherein the second moving device may relatively move the temperature adjusting device and the N number of the third moving devices with respect to the semiconductor wafer held by the holder.

[25] Aspect 25 of the present invention is a semiconductor wafer testing system comprising: a testing device that tests one or more device under tests (DUTs) formed in a semiconductor wafer; a probe card that is electrically connected to the testing device; and the semiconductor wafer handling apparatus of any one of Aspects 1 to 24.

According to one or more embodiments of the present invention, the holder holds the semiconductor wafer while exposing the first and second surfaces of the semiconductor wafer, and the temperature adjusting device that is independent of the holder contacts the second surface of the semiconductor wafer and adjusts a temperature of the DUTs. Therefore, it is possible to speed up the temperature adjustment of the DUTs.

### BRIEF DESCRIPTION OF DRAWINGS

FIG. 1 is a diagram showing the overall configuration of the semiconductor wafer testing system and the internal structure of the prober in the first embodiment of the present invention.

FIG. 2 is a cross-sectional view of the thermal head and optical probe unit and a block diagram showing the control system in the first embodiment of the present invention.

FIG. 3A is a plan view of the holder in the first embodiment of the present invention, and FIG. 3B is a cross-sectional view taken along line IIIB-IIIB in FIG. 3A.

FIG. 4 is a plan view of the thermal head and optical probe unit in the first embodiment of the present invention.

FIG. 5A and FIG. 5B are cross-sectional and plan views showing a modified example of the thermal head and the optical probe unit in the first embodiment of the present invention.

FIG. 6 is a cross-sectional view showing the probe card, the thermal head and the optical probe unit in the second embodiment of the present invention.

FIG. 7 is a cross-sectional view of the probe card and thermal head in the third embodiment of the present invention.

FIG. 8A to FIG. 8C are cross-sectional views showing the method of pressing the semiconductor wafer against the probe card by the prober in the first embodiment of the present invention.

FIG. 9 is a diagram showing the overall configuration of the semiconductor wafer testing system and the internal structure of the prober in the fourth embodiment of the present invention.

### DETAILED DESCRIPTION OF EMBODIMENTS

Hereinafter, embodiments of the invention will be described with reference to the drawings.

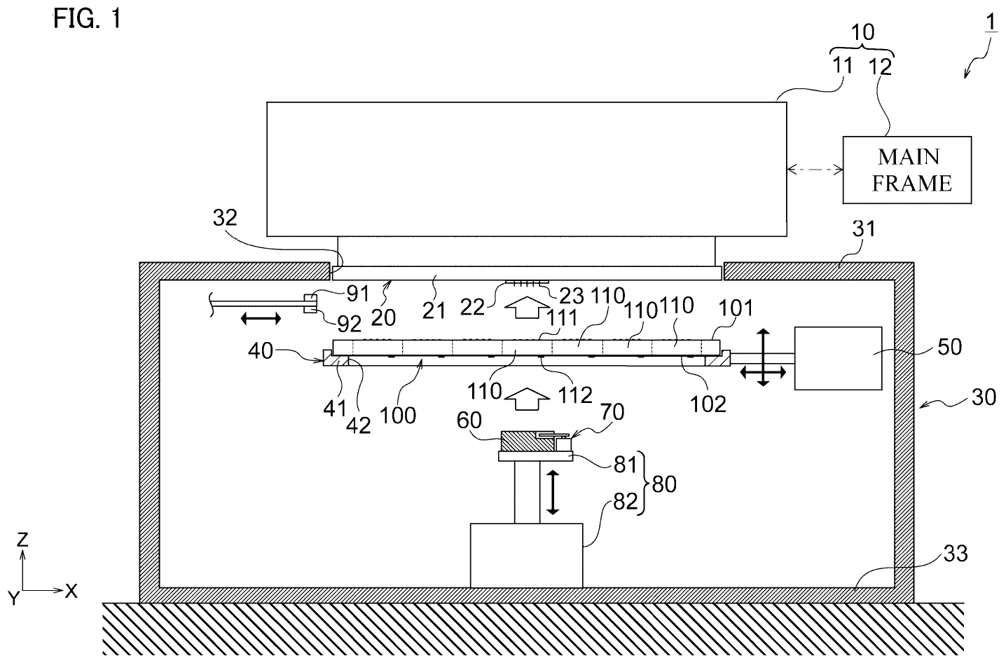

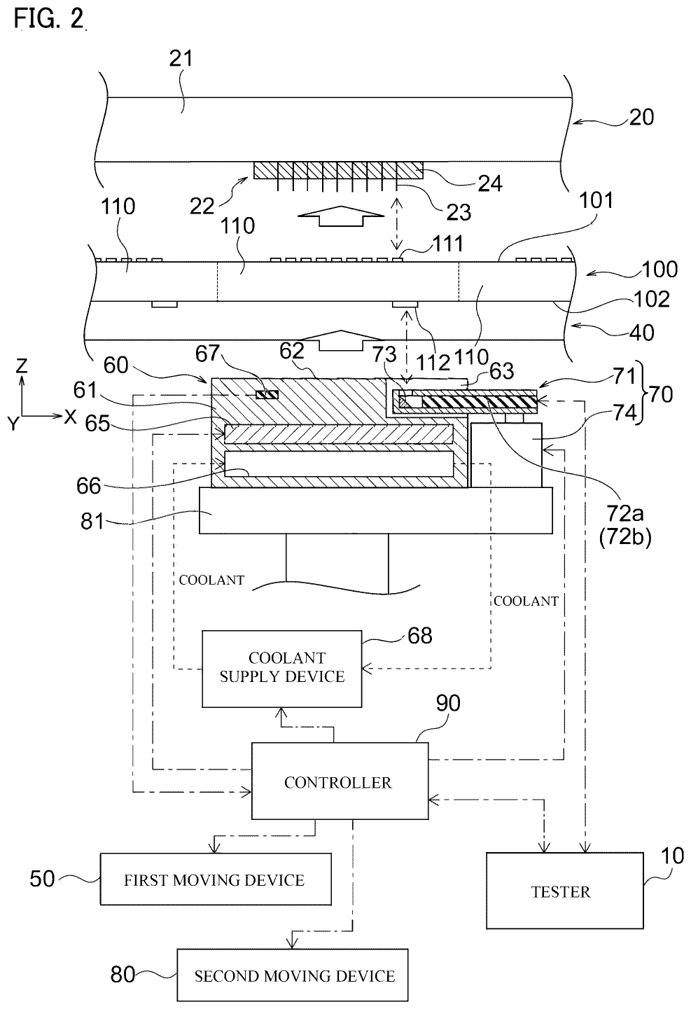

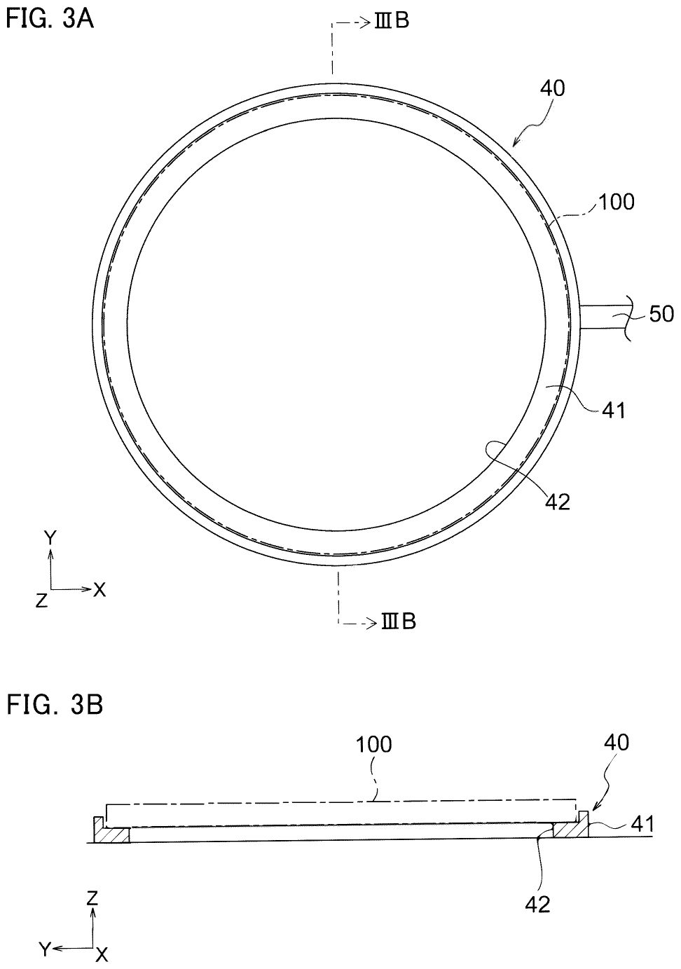

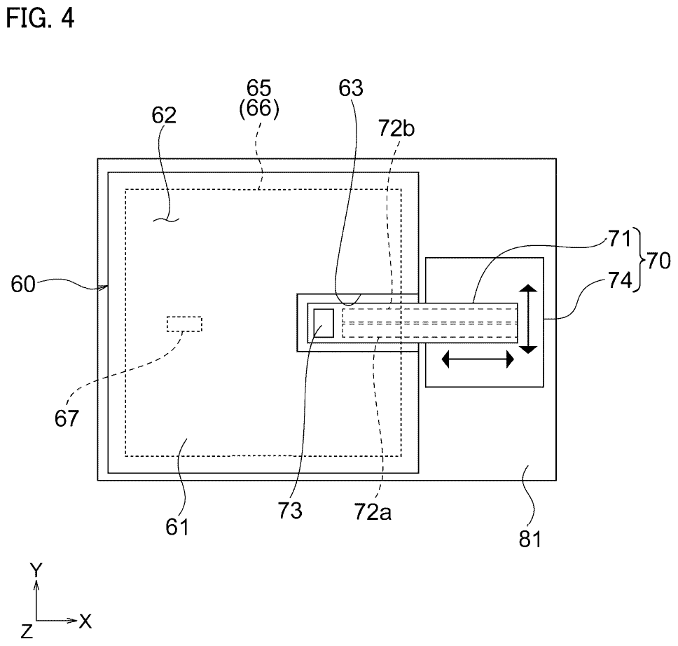

FIG. 1 is a diagram showing the overall configuration of the semiconductor wafer testing system 1 and the internal structure of the prober 30 in the first embodiment of the present invention. FIG. 2 is a cross-sectional view of the thermal head 60 and optical probe unit 70 and a block diagram showing the control system in the first embodiment of the present invention. FIG. 3A and FIG. 3B are plan and cross-sectional views showing the holder 40 in the first embodiment of the present invention. FIG. 4 is a plan view of the thermal head 60 and optical probe unit 70 in the first embodiment of the present invention.

The semiconductor wafer testing system 1 in the first embodiment of the present invention is a system that tests a DUT 110 formed in a semiconductor wafer 100. As shown in FIG. 1, the semiconductor wafer testing system 1 includes a tester 10, a probe card 20, and a prober 30. The prober 30 corresponds to an example of the “semiconductor wafer handling apparatus” in the aspect of the present invention.

The plurality of the DUTs 110 are formed in the semiconductor wafer 100. Each of the DUTs 110 that is the test target of the semiconductor wafer testing system 1 is a device capable of handling electrical and optical signals. That is, the DUT 110 is a hybrid circuit device including an electronic circuit and an optical circuit. The optical circuit is formed using, for example, silicon photonics technology. The DUT 110 includes a terminal 111 for inputting and outputting an electrical signal and an optical connection part 112 for inputting and outputting an optical signal. Although not particularly limited, for example, a grating coupler can be exemplified as a specific example of the optical connection part 112. While the terminal 111 is disposed on the upper surface (first surface) 101 of the semiconductor wafer 100, the optical connection part 112 is disposed on the lower surface (second surface) 102 of the semiconductor wafer 100.

During the test of the DUT 110, an electrical signal is input and output to and from the DUT 110 via the terminal 111, and an optical signal is input and output to and from the DUT 110 via the optical connection part 112. When the test is completed, for example, the DUT 110 is individualized by dicing the semiconductor wafer 100, and the individualized DUT 110 is mounted on a board to which an optical fiber and like is connected to form a final product. This final product is, for example, a CPO (Co-Packaged Optics) device.

The tester 10 is a test apparatus that tests the DUT 110 formed in the semiconductor wafer 100 using electrical and optical signals. As shown in FIG. 1, the tester 10 includes a test head 11 and a main frame (tester body) 12. The test head 11 is connected to the main frame 12 via a cable. The probe card 20 is electrically connected to the test head 11. The probe card 20 enters the inside of the prober 30 through an opening 32 formed in an upper base 31 of the prober 30. The probe card 20 is relatively fixed to the prober 30.

The probe card 20 includes a wiring board 21 and a probe head 22 mounted on wiring board 21. The probe head 22 corresponds to one DUT 110 on the semiconductor wafer 100. As shown FIG. 2, the probe head 22 includes a plurality of probes 23 and a housing 24. The probe 23 corresponds to an example of the “contactor” in the aspect of the present invention.

The probe 23 is an electrical probe that contacts the terminal 111 of the DUT 110 of the semiconductor wafer 100. The plurality of probes 23 are disposed to correspond to the plurality of terminals 111 included in one DUT 110 on the semiconductor wafer 100. Although not particularly limited, for example, a pogo pin, a vertical probe needle, a cantilever-type probe needle, an anisotropic conductive rubber sheet, a bump provided on a membrane, or a contactor manufactured using MEMS technology can be exemplified as a specific example of the probe 23.

The probes 23 are held by the housing 24, and the probe head 22 is mounted to the wiring board 21 by fixing the housing 24 to the wiring board 21 by screws or the like. The wiring board 21 may directly hold the probes 23, and the housing 24 can be omitted in this case.

As shown FIG. 1 and FIG. 2, the prober 30 includes a holder 40, a first moving device 50, a thermal head 60, an optical probe unit 70, a second moving device 80, and a controller 90. The thermal head 60 corresponds to an example of the “temperature adjusting device” in the aspect of the present invention.

In the present embodiment, the semiconductor wafer 100 held by the holder 40 is aligned (positioned) with respect to the probe card 20 by the first moving device 50. Further, the thermal head 60 is brought into contact with the lower surface 102 of the semiconductor wafer 100 by the second moving device 80, and the temperature of the DUT is adjusted by the thermal head 60. Then, the semiconductor wafer 100 is pressed against the probe card 20 by the first and second moving devices 50 and 80 to electrically connect the semiconductor wafer 100 and the probe card 20. In this state, the optical probe 71 is aligned (positioned) with respect to the optical connection part 112 of the DUT 110 by the optical probe unit 70, and then, the tester 10 inputs and outputs electrical signals to and from the DUT 110 via the probe card 20 and inputs and outputs optical signals to and from the DUT 110 via the optical connection part 112 to test the DUT 110.

The holder 40 is a member that holds the semiconductor wafer 100. The holder 40 holds the lower surface 102 of the semiconductor wafer 100, and the entire upper surface 101 of the semiconductor wafer 100 is exposed. As shown in FIG. 3A and FIG. 3B, the holder 40 includes a circular annular holding part 41. The holding part 41 has an opening 42 with an inner diameter smaller than the outer diameter of the semiconductor wafer 100. Therefore, the holding part 41 holds the outer peripheral part of the lower surface 102 of the semiconductor wafer 100. The part of the lower surface 102 of the semiconductor wafer 100 other than the outer peripheral part (the part of the lower surface 102 of the semiconductor wafer 100 that is more inward than the outer peripheral part) is exposed through the opening 42. The holder 40 may include a holding mechanism that sucks and holds the outer peripheral part of the semiconductor wafer 100. Alternatively, the holder 40 may include a holding mechanism that holds the outer peripheral part of the semiconductor wafer 100 by a mechanical clamp.

The first moving device 50 is a device that may comprises a central processing unit (CPU) or may be controlled by the controller 90, and moves the holder 40. The first moving device 50 is capable of moving the holder 40 in XYZ axis directions in the figure and rotating (Oz) the holder 40 around the Z axis. The semiconductor wafer 100 is aligned (positioned) with respect to the probe card 20 by the first moving device 50 so that the plurality of terminals 111 of the DUT 110 respectively face the plurality of probe 23 of the probe head 22. The first moving device 50 is fixed to, for example, the frame of the prober 30. As long as the installing position of the first moving device 50 is a location where the first moving device 50 is relatively fixed to the frame of the prober 30, the installing position of the first moving device 50 is not limited to the above. For example, the first moving device 50 may be fixed to the upper base 31 or lower base 32 of the prober 30.

Although not particularly limited, the first moving device 50 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The thermal head 60 is a temperature adjusting device that contacts the lower surface 102 of the semiconductor wafer 100 and adjusts the temperature of the DUT 110. As shown in FIG. 2, the thermal head 60 includes a contact member 61, a heater 65, a flow path 66, and a temperature sensor 67.

The contact member 61 is a block-shaped member having a flat contact surface 62 that contacts the lower surface 102 of the semiconductor wafer 100. The heater 65 is embedded in the contact member 61. The heater 65 is disposed inside the contact member 61 so that the heater 65 corresponds to the entire area of the contact surface 62. Although not particularly limited, a ceramic heater such as an aluminum nitride heater, a silicon nitride heater, and a PTC heater, a polyimide heater, and a cartridge heater can be exemplified as a specific example of the heater 65. The heater 65 is connected to the controller 90. The heater 65 generates heat by the power supplied from the controller 90 and heats the DUT 110 via the contact member 61. The contact surface 62 corresponds to the “first contact surface” in the aspect of the present invention.

The flow path 66 through which a coolant having a temperature lower than room temperature passes is formed inside the contact member 61. The flow path 66 is also disposed inside the contact member 61 so that the flow path 66 corresponds to the entire area of the contact surface 62. A coolant supply device 68 is connected to the flow path 66. As the coolant that is supplied from the coolant supply device 68 passes through the flow path 66, the DUT 110 is cooled via the contact member 61. A liquid or a gas may be used as the coolant flowing through the flow path 66. Although not particularly limited, for example, water and fluorine-based inert liquid can be exemplified as a specific example of a liquid coolant. On the other hand, for example, air and nitrogen can be exemplified as a specific example of gas coolant.

The configuration of the temperature adjusting device that adjusts the temperature of the DUT 110 is not limited to the above. For example, instead of a heater, a hot medium having a temperature higher than room temperature may be passed through a flow path in the contact member 61. Alternatively, a Peltier element may be used as the heater, or a Peltier element may be used instead of the coolant. The temperature adjusting device may not include either a heating device (e.g., a heater 65B described later) or a cooling device (e.g., a cooling block 61B described later).

The temperature sensor 67 is also embedded in the contact member 61. The temperature sensor 67 is disposed inside the contact member 61 so that the temperature sensor 67 is located near the contact surface 62. The temperature sensor 67 detects the temperature of the DUT 110 via the contact surface 62. The temperature sensor 67 is connected to the controller 90 so that the temperature sensor 67 can output the detection result to the controller 90.

As shown in FIG. 2 and FIG. 4, the optical probe unit 70 includes an optical probe 71 and a third moving device 74. The optical probe 71 is an optical input/output part for inputting and outputting optical signals to and from the optical connection part 112 formed on the lower surface 102 of the semiconductor wafer 100. The optical probe 71 includes optical fibers 72a and 72b and a mirror 73.

Each of the optical fibers 72a and 72b is disposed so that the optical axis thereof is along the XY plane in the figure, and the pair of optical fibers 72a and 72b are disposed in substantially parallel. The optical fibers 72a and 72b are connected to the tester 10 to transmit optical signals. The mirror 73 is disposed on the optical axes of the optical fibers 72a and 72b.

When testing the DUT 110, in a state where the end of the optical probe 71 faces the optical connection part 112 of the semiconductor wafer 100, an optical signal input from the tester 10 is output from one optical fiber 72a toward the mirror 73, and the optical signal is reflected by the mirror 73 and is input to the optical connection part 112 of the semiconductor wafer 100. On the other hand, an optical signal output from the optical connection part 112 of the semiconductor wafer 100 is reflected by the mirror 73 and is input to the tester 10 via the other optical fiber 72b. That is, in the present embodiment, one optical fiber 72a functions as an optical transmission path for input, and the other optical fiber 72b functions as an optical transmission path for output.

In the present embodiment, although the optical probe 71 inputs and outputs optical signals in a non-contact state with the optical connection part 112 of the semiconductor wafer 100, the optical probe 71 and the optical connection part 112 may be in contact with each other. The optical probe 71 may include optical elements other than the optical fibers 72a and 72b and the mirror 73 as an optical transmission path for transmitting optical signals.

The optical probe 71 is supported by a third moving device 74. The third moving device 74 is an alignment device that aligns (positions) the optical probe 71 with respect to the optical connection part 112 of the semiconductor wafer 100. That is, in the present embodiment, the alignment (positioning) of the optical probe 71 with respect to the optical connection part 112 can be performed independently of the alignment (positioning) of the terminal 111 of the DUT 110 with respect to the electric probe 23 of the probe card 20. The third moving device 74 is capable of moving the optical probe 71 in the X and Y axis directions in the figure and rotating (θz) the optical probe 71 around the Z axis. The degree of freedom of the third moving device 74 may be six degrees of freedom including the movement in the Z axis direction and the rotations (θx and θy) around the X and Y axes in addition to the above three degrees of freedom.

Although not particularly limited, the third moving device 74 includes, for example, an actuator, a transmission mechanism, and a guide mechanism. Although not particularly limited, for example, a motor including an electric motor (rotary motor, linear motor, etc.), and an electric actuator including the electric motor and a piezoelectric actuator (actuator using a piezoelectric element) can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The second moving device 80 is a device that may comprises a central processing unit (CPU) or may be controlled by the controller 90, and moves the thermal head 60 and the optical probe unit 70. As shown in FIG. 1, the second moving device 80 includes a support member 81 and a lifting mechanism 82 that moves the support member 81 in the Z axis direction.

The thermal head 60 and the optical probe unit 70 are supported by a flat support member 81. Specifically, as shown in FIG. 2 and FIG. 4, the contact member 61 of the thermal head 60 and the third moving device 74 of the optical probe unit 70 are fixed to the support member 81. Therefore, the third moving device 74 is capable of relatively moving the optical probe 71 with respect to the thermal head 60.

A groove 63 is formed in the contact member 61 of the thermal head 60. The groove 63 is formed in the contact member 61 so that the groove 63 opens to the contact surface 62 that contacts the semiconductor wafer 100. The optical probe 71 is inserted in the groove 63. A space is secured between the optical probe 71 and the groove 63 so that the optical probe 71 can be moved and rotated by the third moving device 74 described above.

It is possible to increase the contact area of the thermal head 60 with the semiconductor wafer 100 while the optical probe 71 faces the optical connection part 112 of the semiconductor wafer 100 by mutually overlapping the contact member 61 and the optical probe 71. As a result, the temperature of the DUT 110 can be efficiently adjusted by the thermal head 60, and the DUT 110 can be stably pressed against the probe card 20. The groove 63 corresponds to an example of the “recess” in the aspect of the present invention.

As shown in FIG. 1, the lifting mechanism 82 is installed on the lower base 33 of the prober 30 so that the support member 81 faces the probe head 22 of the probe card 20 in the Z axis direction in the figure. When the lifting mechanism 82 raises the support member 81, the thermal head 60 contacts the lower surface 102 of the semiconductor wafer 100, and the end of the optical probe 71 of the optical probe unit 70 faces the optical connection part 112 of the semiconductor wafer 100. The second moving device 80 is a moving device independent of the above-described first moving device 50 and is capable of moving the thermal head 60 and the optical probe unit 70 independently of the holder 40.

Although not particularly limited, the lifting mechanism 82 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

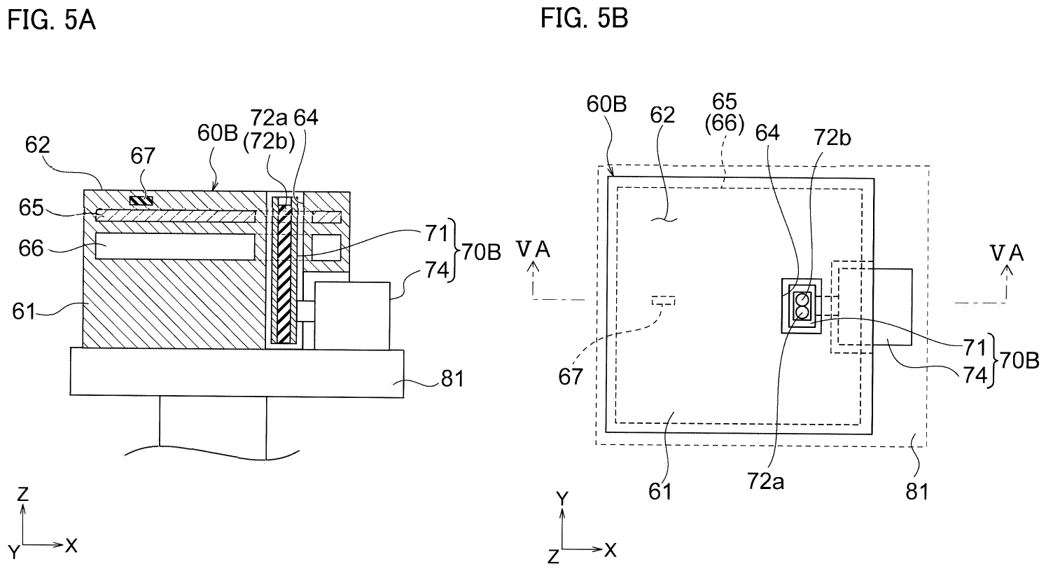

The configuration of the thermal head and the optical probe unit is not limited to the above. For example, the thermal head and the optical probe unit may be configured as shown in FIG. 5A and FIG. 5B. FIG. 5A and FIG. 5B are cross-sectional and plan views showing a modified example of the thermal head and the optical probe unit in the embodiment of the present invention. FIG. 5A is a cross-sectional view along the line VA-VA in FIG. 5B.

In the thermal head 60B and the optical probe unit 70B shown in FIG. 5A and FIG. 5B, an insertion hole 64 is formed in the contact member 61 along the Z axis direction so that the insertion hole 64 opens to the contact surface 62. The optical probe 71 is inserted in the insertion hole 64. In the modified example, the optical probe 71 does not include a mirror 73 because the optical axes of the optical fibers 72a and 72b are disposed in the Z axis direction in the figure. A space is secured between the optical probe 71 and the insertion hole 64 so that the optical probe 71 can be moved and rotated by the third moving device 74. Thus, it is possible to increase the contact area of the thermal head 60 with the semiconductor wafer 100 while the optical probe 71 faces the optical connection part 112 of the semiconductor wafer 100 by disposing the optical probe 71 in the insertion hole 64 formed in the contact member 61.

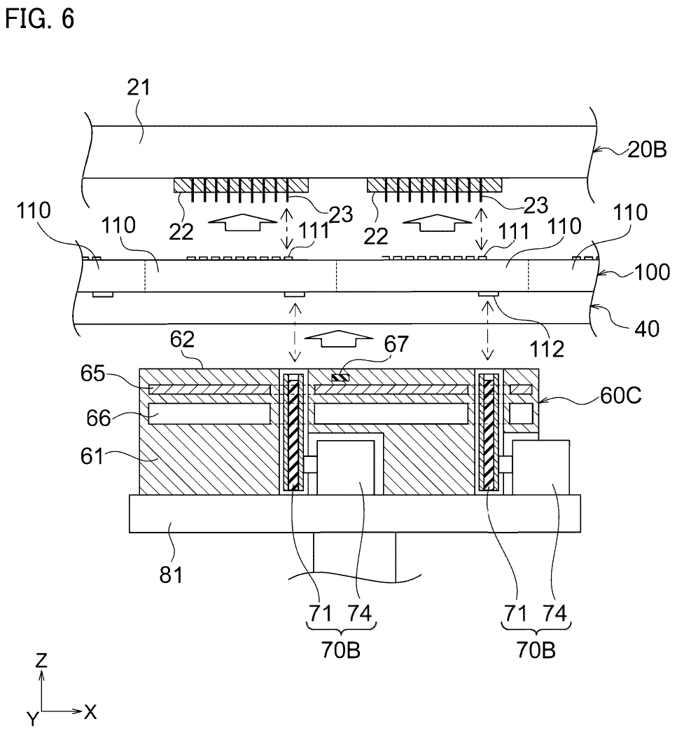

Although only one DUT 110 is tested in one touchdown in the above-described embodiment, a plurality of DUTs 110 may be simultaneously tested in one touchdown. FIG. 6 is a cross-sectional view showing the probe card 20B, the thermal head 60C and the optical probe unit 70B in the second embodiment of the present invention.

For example, as shown in FIG. 6, the case of simultaneously testing two DUTs 110 in one touchdown will be described. In this case, the probe card 20B includes two probe heads 22 disposed on the wiring board 21 to correspond to the two DUTs 110. Furthermore, the contact surface 62 of the thermal head 60C has a size capable of contacting the area corresponding to the two DUTs 110 in the lower surface 102 of the semiconductor wafer 100, and it is possible to adjust the temperature of the two DUTs 110 by one thermal head 60C. On the other hand, two optical probe units 70B are disposed on the support member 81 of the second moving device 80 to correspond to the two DUTs 110. Each of the optical probe units 70B includes an optical probe 71 and a third moving device 74, similar to the above-described optical probe unit 70B. The thermal head 60C and the two optical probe units 70B are disposed on the same support member 81.

Instead of the thermal head 60C, two thermal heads 60B may be disposed on the support member 81 to correspond to the two DUTs 110. In the example shown in FIG. 6, the optical probe unit 70 shown in FIG. 2 and FIG. 4 may be used instead of the optical probe unit 70B.

Although not particularly limited, N number of DUTs 110 that are simultaneously tested in one touchdown is preferably a natural number greater than or equal to 1 and less than or equal to 8 (1≤N≤8). In this case, the probe card includes N number of probe heads 22, and the contact surface 62 of the thermal head has a size capable of contacting the N number of the DUTs 110 among all of the DUTs 110 formed on the semiconductor wafer 100, and the thermal head and N number of optical probe units are disposed on the same support member 81.

Therefore, it is sufficient to locally adjust the temperature of the semiconductor wafer 100 by the thermal head 60, and it is also possible to further speed up the temperature adjustment of the DUT 110. The optical probe unit 70 is required for each DUT 110. Therefore, because the N number is not the number of all of the DUTs 110 included in the semiconductor wafer 100 and is less than or equal to 8, it is possible to limit the increase in the number of optical probe units 70. It is more preferable that the N number is a natural number greater than or equal to 1 and less than or equal to 4 (1≤N≤4), and even more preferable that it is a natural number greater than or equal to 1 and less than or equal to 2 (1≤N≤2). The number of all of the DUTs 110 included in the semiconductor wafer 100 is greater than the N number.

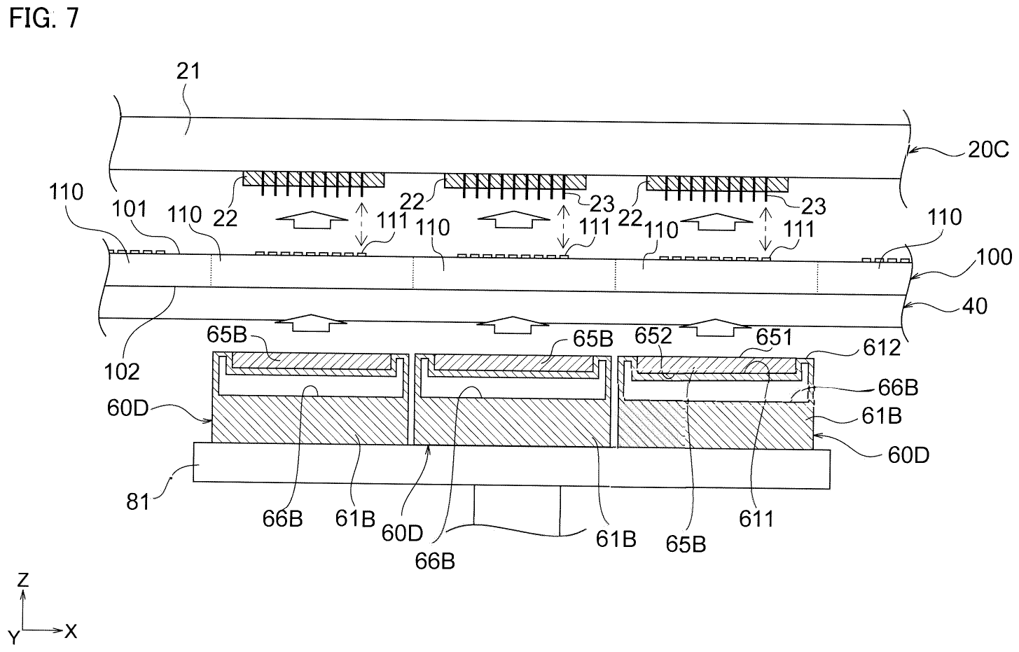

Alternatively, the thermal head may be configured as shown in FIG. 7. FIG. 7 is a cross-sectional view showing the probe card 20C and the thermal head 60D in the third embodiment of the present invention.

In the example shown in FIG. 7, the probe card 20C includes three probe heads 22 disposed on the wiring board 21 to correspond to three DUTs 110. The prober also includes three thermal heads 60D to correspond to the three probe heads 22. The three thermal heads 60D are disposed on the same support member 81.

Each of the thermal heads 60D includes the heater 65B and the cooling block 61B. Although not particularly limited, the heater 65B is a planar heater having an upper surface (first heater surface) 651 that directly contacts the lower surface 102 of the semiconductor wafer 100 and a lower surface (second heater surface) 652 opposite to the upper surface 651. For example, a ceramic heater such as an aluminum nitride heater, a silicon nitride heater, and a PTC heater, a polyimide heater, and a cartridge heater can be exemplified as a specific example of the heater 65B.

The cooling block 61B is a block-shaped member that holds the above-described heater 65B. The cooling block 61B has a concave upper part. The heater 65B is housed in the concave part.

Specifically, the cooling block 61B includes a contact surface 611 and an annular protrusion 612 surrounding the outer periphery of the contact surface 611. The contact surface 611 is in contact with the lower surface 652 of the heater 65B. The heater 65B is held by the cooling block 61B in a state where the upper surface 651 of the heater 65B is exposed. When the thermal head 60D contacts the lower surface 102 of the semiconductor wafer 100, the upper surface 651 of the heater 65B directly contacts the lower surface 102 of the semiconductor wafer 100. The protrusion 612 protrudes upward (in the +Z direction in the figure) from the contact surface 611 and surrounds the outer periphery of the heater 65B.

The protrusion 612 has a height substantially the same as the thickness of the heater 65B. When the upper surface 651 of the heater 65B directly contacts the lower surface 102 of the semiconductor wafer 100, the protrusion 612 also directly contacts the lower surface 102 of the semiconductor wafer 100. That is, the upper surface 651 of the heater 65B and the upper surface of the protrusion 612 constitute the contact surface 62 of the thermal head 60D that contacts the lower surface 102 of the semiconductor wafer 100. The contact surface 611 corresponds to an example of the “second contact surface” in the aspect of the present invention, and the protrusion 612 corresponds to an example of the “contact part” in the aspect of the present invention.

A flow path 66B through which a coolant having a temperature lower than room temperature passes is formed inside the cooling block 61B. The flow path 66B is formed inside the cooling block 61B to correspond to the entire area of the contact surface 611 and to also pass through the inside of the protrusion 612. Although not specifically shown, similar to the above-described contact member 61, the temperature sensor is embedded in the cooling block 61B.

Although not specifically shown, similar to the above-described heater 65, the heater 65B is connected to the controller 90 and generates heat by the power supplied from the controller 90. Although not specifically shown, similar to the above-described flow path 66, a coolant supply device 68 is connected to the flow path 66B. As the coolant that is supplied from the coolant supply device 68 passes through the flow path 66B, the DUT 110 is cooled.

In the example shown in FIG. 7, the upper surface 651 of heater 65B directly contacts the lower surface 102 of the semiconductor wafer 100, thus the heater 65B directly heats the DUT 110. On the other hand, the cooling block 61B cools the heater 65B contacting the semiconductor wafer 100 and also directly cools the semiconductor wafer 100 with the protrusion 612. Since the annular protrusion 612 of the cooling block 61B surrounds the outer periphery of the heater 65B, it is possible to suppress the thermal expansion of the semiconductor wafer 100 due to the heating of the heater 65B, and it is possible to suppress mis-contact between the probe card 20C and the DUT 110.

For example, when the thermal expansion of the semiconductor wafer 100 due to the heating of the heater 65B is small, only the heater 65B may be exposed from the upper surface of thermal head 60D without including the protrusion 612 in cooling block 61B.

The number of probe heads 22 included in the probe card 20C is not particularly limited to the above, for example, the probe card 20C may include only one probe head 22. Similarly, the number of thermal heads 60D included in the prober is not particularly limited to the above as long as it corresponds to the number of probe heads 22. The above-described effect of suppressing thermal expansion is particularly significant when the number of probe heads 22 and the number of thermal heads 60D are multiple. It is preferable that each of the number of probe heads 22 and the number of thermal heads 60D is the above-described N number, therefore it is possible to further speed up the temperature adjustment of the DUT 110.

Although the semiconductor wafer 100 does not include the optical connection part 112 and the prober does not include the optical probe unit 70 in the example shown in FIG. 7, the semiconductor wafer 100 may include the optical connection part 112 and the prober may include the optical probe unit 70 in the example shown in FIG. 7. Alternatively, in the example shown in FIG. 7, instead of the optical probe unit 70, the prober may include the optical probe unit 70B as shown in FIG. 5A and FIG. 5B.

Although the cooling blocks 61B are divided to correspond to the DUTs 110 in the example shown in FIG. 7, a single cooling block 61B may has a size to correspond to the plurality of DUT 110s as explained with reference to FIG. 6.

Returning to FIG. 2, the controller 90 includes, for example, a computer. Although not specifically shown, the computer is an electronic computer that includes a CPU (processor), a main memory (such as a RAM), an auxiliary memory device (such as a hard disk or SSD), an interface, and the like. The control described below is functionally realized, for example, by the controller 90 executing a program. The controller 90 may be configured with a circuit board instead of a computer.

As shown in FIG. 2, the controller 90 is electrically connected to the heater 65, the temperature sensor 67, and the coolant supply device 68. The controller 90 controls the heater 65 and the coolant supply device 68 based on the detection result of the temperature sensor 67 to adjust the temperature of the DUT 110 through the contact member 61. The controller 90 may control the heater 65 and the coolant supply device 68 based on the output of the temperature detecting circuit formed in the semiconductor wafer 100 instead of the temperature sensor 67. Although not particularly limited, for example, a circuit including a thermal diode and formed in the semiconductor wafer 100 can be exemplified as a specific example of the temperature detecting circuit.

The controller 90 is connected to the tester 10 so that the controller 90 is capable of transmitting electrical signals to and from the tester 10. The tester 10 has the function to test the electronic circuit of the DUT 110 and the function to test the optical circuit of the DUT 110. The tester 10 is connected to the optical fibers 72a and 72b of the optical probe 71 so that the tester 10 is capable of transmitting optical signals to and from the optical fibers 72a and 72b of the optical probe 71. The function to test the optical circuit of the DUT 110 includes the function of the light source and the function to measure the intensity of light. The controller 90 is connected to the first to third moving devices 50, 80 and 74 so that the controller 90 is capable of outputting control signals to the first to third moving devices 50, 80 and 74. The controller 90 can control the operation of the moving devices 50, 80 and 74. The tester 10 may not have the function to test the optical circuit of the DUT 110. In this case, an external measuring device having the function to test the optical circuit of the DUT 110 is connected to the optical fibers 72a and 72b of the optical probe 71 so that the external measuring device is capable of transmitting optical signals to and from the optical fibers 72a and 72b of the optical probe 71. The external measuring device is a testing device independent of the tester 10 and is, for example, electrically connected to the tester 10.

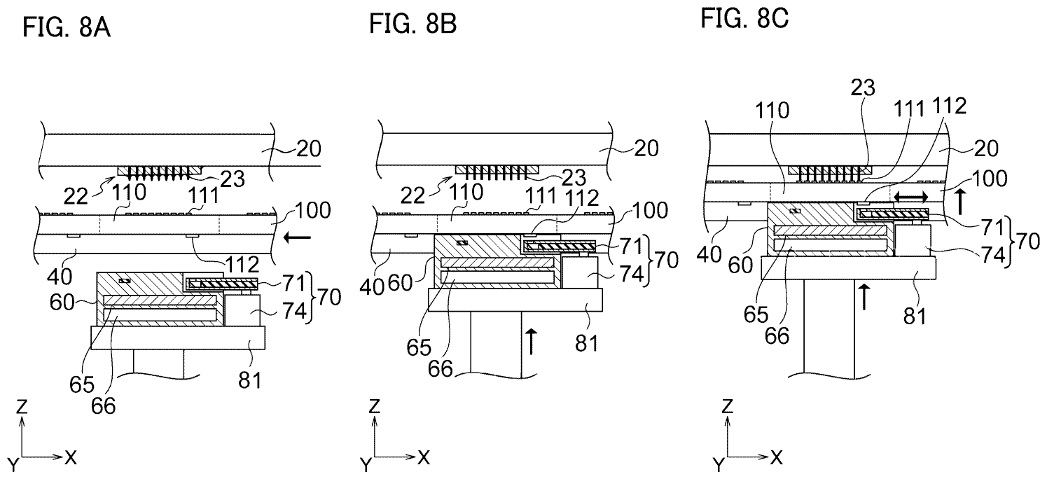

Below, the method of pressing the semiconductor wafer 100 against the probe card 20 by the above-described prober 30 will be explained with reference to FIG. 8A to FIG. 8C. FIG. 8A to FIG. 8C are cross-sectional views showing the method of pressing the semiconductor wafer 100 against the probe card 20 by the prober 30 in the present embodiment.

First, as shown in FIG. 8A, the first moving device 50 moves the holder 40 so that the semiconductor wafer 100 held by the holder 40 faces the probe card 20. At this time, the position of the holder 40 is finely adjusted by the first moving device 50, and the semiconductor wafer 100 is aligned (positioned) with respect to the probe card 20 so that the plurality of terminals 111 of the DUT 110 respectively face the plurality of probes 23 of the probe head 22.

The relative positional relationship between the terminals 111 of the semiconductor wafer 100 and the probes 23 of the probe card 20 is recognized in advance by, for example, the cameras 91 and 92 (refer to FIG. 1) and the image processing function of the controller 90. Specifically, the cameras 91 and 92 can be moved by a moving device not shown in the figures. The camera 91 captures the image of the probe card 20, and another camera 92 captures the image of the semiconductor wafer 100 held by the holder 40. Then, the relative positional relationship between the terminals 111 and the probes 23 is recognized based on these images by the image processing function of the controller 90. Although not shown in the figures, the semiconductor wafer 100 is supplied to the holder 40 from a cassette such as a FOUP (Front-Opening Unified Pod) by a transfer arm.

Next, as shown in FIG. 8B, the second moving device 80 raises the thermal head 60 and the optical probe unit 70 to bring the thermal head 60 into contact with the semiconductor wafer 100 held by the holder 40. At this time, because the outer peripheral part of the semiconductor wafer 100 is held by the holder 40, the contact surface 62 of the thermal head 60 directly contacts the exposed part of the lower surface 102 of the semiconductor wafer 100 that is more inward than the outer peripheral part. When the thermal head 60 contacts the semiconductor wafer 100, the controller 90 starts controlling the heater 65 and the coolant supply device 68 to adjust the temperature of the DUT 110.

Next, as shown in FIG. 8C, while maintaining the contact state between the thermal head 60 and the semiconductor wafer 100, the first moving device 50 raises the holder 40, the second moving device 80 raises the thermal head 60 and the optical probe unit 70, and the semiconductor wafer 100 is pressed against the probe card 20 to electrically connect the semiconductor wafer 100 and the probe card 20. In this state, the plurality of terminals 111 of the DUT 110 are in contact with the plurality of probes 23 of the probe card 20.

Next, the third moving device 74 relatively aligns (positions) the end of the optical probe 71 with respect to the optical connection part 112 of the semiconductor wafer 100 by finely adjusting the position of the optical probe 71. Although not particularly limited, the positional relationship between the optical probe 71 and the optical connection part 112 is recognized based on, for example, the intensity of light output from the optical connection part 112.

Specifically, light output from the light source included in the tester 10 is irradiated from the one optical fiber 72a of the optical probe 71 toward the lower surface 102 of the semiconductor wafer 100 including the optical connection part 112. Then, the other optical fiber 72b receives the light output from the optical connection part 112 via a loopback circuit incorporated in the optical circuit of the DUT 110. While this operation is being performed, the third moving device 74 causes the optical probe 71 to scan along the lower surface 102 of the semiconductor wafer 100. Then, the tester 10 measures the intensity of light output from the optical connection part 112, and the controller 90 stops the movement of the optical probe 71 at a position where the intensity of light is equal to or greater than a predetermined value. As a result, the optical probe 71 is aligned (positioned) with respect to the optical connection part 112.

As with the relative positional relationship between the terminal 111 of the semiconductor wafer 100 and the probe 23 of the probe card 20 described above, the relative positional relationship between the optical probe 71 and the optical connection part 112 may be recognized by cameras and an image processing. In this case, for example, the semiconductor wafer 100 held by the holder 40 is imaged from below with a camera and the thermal head 60 is imaged from above with another camera before the thermal head 60 contacts the semiconductor wafer 100 held by the holder 40. Then, the image processing function of the controller 90 recognizes the relative positional relationship between the optical probe 71 and the optical connection part 112 based on these images. Alternatively, the optical probe 71 may be coarsely aligned with respect to the optical connecting part 112 using image processing, and then the optical probe 71 may be precisely aligned based on the intensity of light.

The alignment of the optical probe 71 with respect to the optical connection part 112 may be performed in a state where the thermal head 60 is in contact with the semiconductor wafer 100 held by the holder 40 (the state shown in FIG. 8B). That is, the alignment of the optical probe 71 with respect to the optical connection part 112 may be performed before electrically connecting the semiconductor wafer 100 and the probe card 20.

Next, the tester 10 inputs an electrical signal to the DUT 110 via the electrical probe 23 and the terminal 111, and the tester 10 also inputs an optical signal to the DUT 110 via the optical probe 71 and the optical connection part 112. Then, the tester 10 determines the quality and characteristics of the DUT 110 based on the electrical signal output from the DUT 110 via the terminal 111 and the electrical probe 23 and the optical signal output from the DUT 110 via the optical connection part 112 and optical probe 71.

In the present embodiment, the holder 40 holds the semiconductor wafer 100 while exposing the upper and lower surfaces 101 and 102 of the semiconductor wafer 100, and the thermal head 60 that is independent of the holder 40 contacts the lower surface 102 of the semiconductor wafer 100 and adjusts a temperature of the DUT 110. Therefore, it is possible to speed up the temperature adjustment of the DUT 110.

In particular, in the present embodiment, the contact surface 62 of the thermal head 60 has a size capable of contacting one to eight DUTs 110 among all of the DUTs 110 formed on the semiconductor wafer 100. Therefore, because the target area for temperature adjustment by the thermal head 60 is small, it is possible to further speed up the temperature adjustment of the DUT 110.

Further, in the present embodiment, the prober 30 includes the third moving device 74 that moves the optical probe 71 independently of the first moving device 50 that aligns the semiconductor wafer 100 with respect to the probe card 20. Therefore, it is possible to relatively align (position) the optical probe 71 with respect to the optical connection part 112 of the DUT 110 in a state where the semiconductor wafer 100 is held by the holder 40. Further, even if the accuracy of the alignment of the optical probe 71 with respect to the optical connection part 112 is higher than that of the electrical probe 23 with respect to the terminal 111, it is possible to align the optical probe 71 with respect to the optical connection part 112 with high accuracy by the third moving device 74.

It should be noted that the above embodiments are described to facilitate understanding of the invention and are not described to limit the invention. It is therefore intended that the elements disclosed in the above embodiments include all design modifications and equivalents to fall within the technical scope of the present invention.

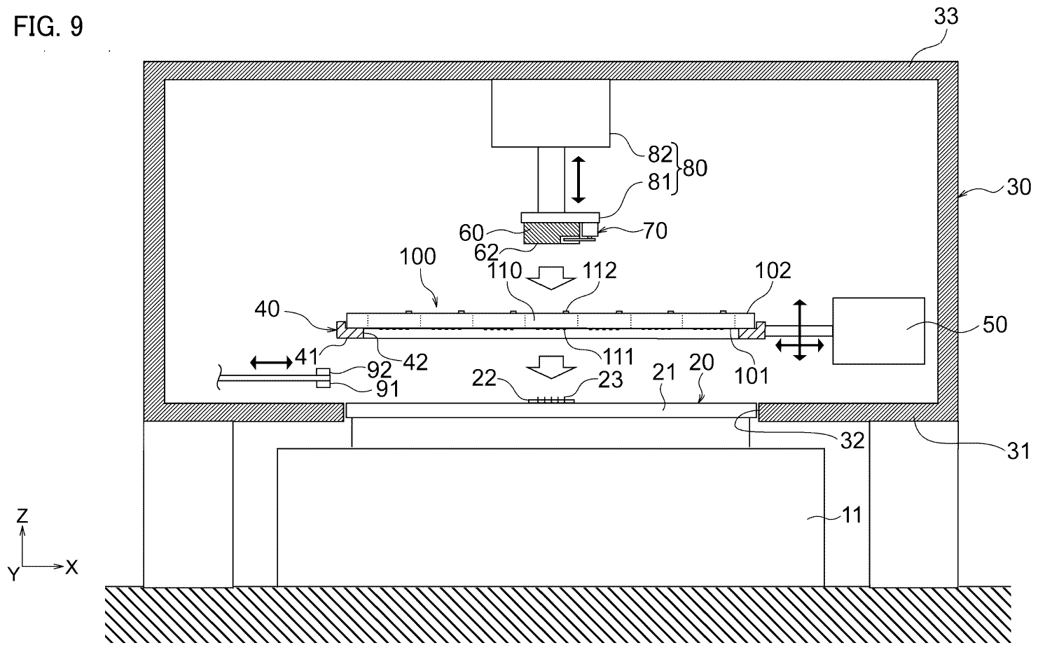

For example, as shown in FIG. 9, the semiconductor wafer testing system 1 may be configured to test the semiconductor wafer 100 in a posture opposite in the vertical direction to that of the above-described embodiments. FIG. 9 is a diagram showing the overall configuration of the semiconductor wafer testing system and the internal structure of the prober in the fourth embodiment of the present invention.

In this case, as shown in FIG. 9, the annular holding part 41 of the holder 40 holds the lower surface (first surface) 101 of the semiconductor wafer 100. The upper surface (second surface) 102 of the semiconductor wafer 100 faces upward, and the entire upper surface 102 is exposed. The probe card 20 is disposed below the holder 40 with the probes 23 facing upward, and the second moving device 80 is disposed above the holder 40 with the contact surface 62 of the thermal head 60 and the optical axis of the optical probe unit 70 facing downward. That is, in the embodiment shown in FIG. 9, all the components except for the holder 40 are inverted from the above-described first embodiment.

Although the DUT 110 of the semiconductor wafer 100 is a hybrid circuit element including an optical circuit and an electronic circuit in the embodiments described with reference to FIG. 1 to FIG. 6, FIG. 8A to FIG. 8C, and FIG. 9, the DUT that is a test target may be an electronic circuit element including no optical circuit. In this case, the prober does not include the optical probe units 70 and 70B.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATIONS OF LETTERS OR NUMERALS

1 . . . Semiconductor wafer testing system
10 . . . Tester
11 . . . Test head
12 . . . Main frame
20, 20B, 20C . . . Probe card
21 . . . Wiring board
22 . . . Probe head
23 . . . Probe
24 . . . Housing
30 . . . Prober
31 . . . Upper base
32 . . . Opening
33 . . . Lower base
40 . . . Holder
41 . . . Holding part
42 . . . Opening
50 . . . First Moving device
60, 60B to 60D . . . Thermal head
61 . . . Contact member
61B . . . Cooling block
611 . . . Contact surface
612 . . . Protrusion
62 . . . Contact surface
63 . . . Groove
64 . . . Insertion hole
65, 65B . . . Heater
651 . . . Upper surface
652 . . . Lower surface
66, 66B . . . Flow path
67 . . . Temperature sensor
68 . . . Coolant supply device
70 and 70B . . . Optical probe unit
71 . . . Optical probe
72a. 72b . . . Optical fiber
73 . . . Mirror
74 . . . Third moving device
80 . . . Second moving device
81 . . . Support member
82 . . . Lifting mechanism
90 . . . Controller
91 and 92 . . . Camera
100 . . . Semiconductor wafer
101 . . . Upper surface
102 . . . Lower surface
110 . . . DUT
111 . . . Terminal
112 . . . Optical connection part

What is claimed is:

1. A semiconductor wafer handling apparatus that moves a semiconductor wafer comprising a first surface on which a terminal of one or more device under tests (DUTs) is disposed and presses the terminal against a contactor of a probe card, the semiconductor wafer handling apparatus comprising:
a holder that holds the semiconductor wafer such that the first surface and a second surface of the semiconductor wafer are at least partially exposed;
a first moving device that relatively moves the holder with respect to the probe card;
a temperature adjusting device that contacts the second surface of the semiconductor wafer and adjusts a temperature of the DUTs; and
a second moving device that relatively moves the temperature adjusting device with respect to the semiconductor wafer held by the holder.

2. The semiconductor wafer handling apparatus according to claim 1, wherein
the temperature adjusting device comprises a first contact surface that contacts the second surface of the semiconductor wafer,
the first contact surface has a size capable of contacting N number of the DUTs formed in the semiconductor wafer, and
the N number is a natural number greater than or equal to 1 and less than or equal to 8.

3. The semiconductor wafer handling apparatus according to claim 1, wherein
the holder holds an outer peripheral part of the second surface of the semiconductor wafer such that the second surface of the semiconductor wafer is at least partially exposed, and
the temperature adjusting device contacts an exposed part of the second surface from the holder.

4. The semiconductor wafer handling apparatus according to claim 1, wherein
the holder comprises an annular holding part that holds an outer peripheral part of the second surface of the semiconductor wafer.

5. The semiconductor wafer handling apparatus according to claim 1, wherein
the holder holds an outer peripheral part of the first surface of the semiconductor wafer, and
the temperature adjusting device contacts the second surface of the semiconductor wafer.

6. The semiconductor wafer handling apparatus according to claim 1, wherein
the holder comprises an annular holding part that holds an outer peripheral part of the first surface of the semiconductor wafer.

7. The semiconductor wafer handling apparatus according to claim 1, wherein
the temperature adjusting device comprises:
a contact block that comprises a first contact surface that contacts the second surface of the semiconductor wafer; and
at least one of a heating device that heats the DUTs via the contact block and a cooling device that cools the DUTs via the contact block.

8. The semiconductor wafer handling apparatus according to claim 1, wherein
the temperature adjusting device comprises:
a heating device that contacts the second surface of the semiconductor wafer and heats the DUTs; and
a cooling block that holds the heating device and comprises a flow path through which a coolant passes.

9. The semiconductor wafer handling apparatus according to claim 8, wherein
the cooling block comprises a contact part that surrounds an outer periphery of the heating device and contacts the second surface of the semiconductor wafer.

10. The semiconductor wafer handling apparatus according to claim 9, wherein
the heating device comprises a planar heater,
the planar heater comprises:
a first heater surface that contacts the second surface of the semiconductor wafer; and
a second heater surface opposite to the first heater surface, and
the cooling block comprises a second contact surface contacting the second heater surface.

11. The semiconductor wafer handling apparatus according to claim 9, wherein
the flow path passes through an inside of the contact part.

12. The semiconductor wafer handling apparatus according to claim 8, further comprising:
a plurality of temperature adjusting devices including the temperature adjusting device.

13. The semiconductor wafer handling apparatus according to claim 12, wherein
the temperature adjusting devices individually correspond to the DUTs included in the semiconductor wafer.

14. The semiconductor wafer handling apparatus according to claim 1, comprising:
a controller that controls the first and second moving devices to bring the holder and the temperature adjusting device closer to the probe card in a pressing direction of the DUTs against the probe card, and to press the terminal of the DUTs against the contactor of the probe card.

15. The semiconductor wafer handling apparatus according to claim 1, wherein:
each of the DUTs comprises an optical connection part, and
the semiconductor wafer handling apparatus further comprises:
an optical probe that inputs and outputs an optical signal to and from the optical connection part; and
a third moving device that moves the optical probe.

16. A semiconductor wafer testing system comprising:
a testing device that tests one or more device under tests (DUTs) formed in a semiconductor wafer;
a probe card that is electrically connected to the testing device; and
the semiconductor wafer handling apparatus according to claim 1.
